(19) United States
(12) Patent Application Publication
(10) Pub. No.: US 2012/0182022 A1
(43) Pub. Date: Jul. 19, 2012

(54) METHOD OF INDICATING VOLTAGE, VOLTAGE INDICATING APPARATUS, AND BATTERY PACK

(76) Inventors: Takaaki KINOUCHI, Minamiawaji-shi (JP); Tomonari Ikemachi, Sumoto-shi (JP); Hiroki Teraoka, Sumoto-shi (JP)

(21) Appl. No.: 13/351,421

(22) Filed: Jan. 17, 2012

(30) Foreign Application Priority Data
Jan. 18, 2011 (JP) 2011-007942

(51) Int. Cl. G01R 31/36; G01R 27/26

(52) U.S. Cl. 324/435; 324/658

(57) ABSTRACT

One terminal of a switch 53 is connected to a resistor 51 having its other terminal connected to a rechargeable battery, and the other terminals connected through a resistor 54 to a capacitor 55. Another capacitor 52 is connected to the node between the switch 53 and the resistor 51. Initially, while the switch 53 is in the OFF state, the rechargeable battery charges the capacitor 52 towards the battery voltage through the resistor 51. When the switch 53 is turned ON, capacitor 55 and capacitor 52 become connected in parallel and the voltage across capacitor 55 rises within a short time period. When the switch 53 again turns OFF, voltage indication continues in compliance with the voltage across the capacitor 55 even as that voltage decays according to the time constant of the parallel circuit formed by the capacitor 55 and a series-connection of resistors 71, 72.

### BACKGROUND OF THE INVENTION

1. Field of the Invention

The present invention relates to a method of indicating voltage that displays information corresponding to the voltage of a power source, to a voltage indicating apparatus, and to a battery pack provided with the voltage indicating apparatus.

2. Description of the Related Art

Power source voltage level information can be visually acquired in some existing electrical equipment that use a power source with varying voltage. When the power source utilizes batteries that decrease in voltage with use, continuous indication of voltage information can further discharge the batteries and decrease the battery voltage. Consequently, display of battery voltage information is often limited only to instances initiated by operator action.

Refer to Japanese Laid-Open Patent Publication 2001-70,242 A.

For example, a battery light source apparatus is disclosed in JP 2001-70242. In this apparatus, when a switch for indicating remaining capacity is ON, an activating circuit illuminates a light emitting diode (LED) array based on battery voltage measured by a voltage detection circuit.

### SUMMARY OF THE INVENTION

However, an apparatus that stops displaying remaining capacity when the remaining capacity indicating switch turns OFF makes it difficult for the operator to visually acquire the remaining capacity. Methods of extending the period for displaying remaining capacity after the remaining capacity indicating switch turns OFF have been considered. For example, a capacitor can be provided in the remaining capacity indicating circuit that is charged to a voltage corresponding to the battery voltage and discharged with a given time constant to display remaining capacity corresponding to the voltage across the capacitor.

Based on technology disclosed in JP 2001-70242, the voltage detection circuit and/or the activation circuit can be provided with a circuit having a relatively long time constant that is on the order of seconds for example. In that case, when the remaining capacity indicating switch is turned ON for a time shorter than a given period, the time that the LED array remains illuminated after the indicating switch turns OFF tends to lengthen with the length of time the switch is held ON. Specifically, this system has the problem that the time that remaining capacity is displayed after operator activation of the indicating switch depends on the length of time that the switch is activated.

The present invention was developed considering the circumstances described, above. Thus, it is a primary object of the present invention to provide a method of indicating voltage, voltage indicating apparatus, and battery pack that continues to indicate power source voltage after an operator action to display voltage, and continued voltage display does not depend on the length of time of the operator action.

The method of indicating voltage of the present invention displays power source voltage with a voltage indicating apparatus provided with a capacitor connected to an external power source through series-connection of a resistor circuit and a switch circuit, a second resistor circuit connected in parallel with the capacitor, and a display section that makes indications based on the voltage across the capacitor. The resistor circuit is established closer to the power source than the switch circuit, a second capacitor is provided that is connected to the node between the resistor circuit and the switch circuit, and the switch circuit turns OFF after it is switched ON.

The power source in the method of indicating voltage of the present invention is a battery (or batteries).

In the method of indicating voltage of the present invention, a third resistor circuit is connected in series with the series-connection of the capacitor, the switch circuit, and the second capacitor; and the length of time that the switch circuit is in the ON state is longer than a time related to the time constant of the series circuit that includes the third resistor circuit.

The voltage indicating apparatus of the present invention is provided with a capacitor connected to an external power source through series-connection of a resistor circuit and a switch circuit, a second resistor circuit connected in parallel with the capacitor, and a display section that makes indications based on the voltage across the capacitor. The resistor circuit is connected closer to the power source than the switch circuit, and a second capacitor is provided that is connected to the node between the resistor circuit and the switch circuit.

The power source in the voltage indicating apparatus of the present invention is a battery (or batteries).

In the voltage indicating apparatus of the present invention, a third resistor circuit is connected in series with the series-connection of the capacitor, the switch circuit, and the second capacitor.

In the voltage indicating apparatus of the present invention, the display section makes prescribed indications when the voltage across the capacitor is greater than a prescribed voltage.

In the voltage indicating apparatus of the present invention, the display section has a voltage divider circuit that divides the power source voltage when the voltage across the capacitor is greater than a prescribed voltage, a power supply circuit that generates a reference voltage from the power source voltage when the voltage across the capacitor is greater than a second voltage that is different from the prescribed voltage, comparator circuits that compare the voltage divider circuit voltage with voltages divided from the reference voltage, and display devices that illuminate according to the comparator circuit results.

In the voltage indicating apparatus of the present invention, the second voltage is lower than the prescribed voltage.

In the voltage indicating apparatus of the present invention, the display section has a voltage divider circuit that divides the power source voltage in compliance with voltage rise across the capacitor, a power supply circuit that generates a reference voltage from the power source voltage in compliance with voltage rise across the capacitor, comparator circuits that compare the voltage divider circuit voltage with voltages divided from the reference voltage, and display devices that illuminate according to the comparator circuit results.

The battery pack of the present invention is provided with the voltage indicating apparatus described above and a rechargeable battery (or batteries), which has its voltage displayed by the voltage indicating apparatus.

In the present invention, a series-connected resistor circuit and switch circuit are connected between the external power source and the capacitor, the resistor circuit is connected to the power source side, a second capacitor is connected to the node between the resistor circuit and the switch circuit, and during the initial OFF period of the switch circuit the power source charges the second capacitor towards the power source voltage through the resistor circuit. When the switch circuit is turned ON, the capacitor becomes connected in parallel with the second capacitor through the switch circuit and the voltage across the capacitor rapidly increases to a voltage related to the power source voltage. When the switch circuit turns OFF, display based on the power source voltage continues while the voltage across the capacitor decays according to the time constant of the parallel-connection of the capacitor and second resistor circuit. Consequently, the continued display time does not depend on the time that the switch circuit was in the ON state.

In the present invention, since the battery voltage is indicated, remaining battery capacity can be accurately ascertained.

In the present invention, since a third resistor circuit is connected in series with the series-connection of the capacitor, the switch circuit, and the second capacitor, current flowing from the second capacitor through the switch circuit to the capacitor when the switch circuit is turned ON is prevented from exceeding the allowable current (rated current) of the switch circuit. Further, when the time that the switch circuit is held on by the operator is sufficiently longer than a time related to the time constant of the series-connection of the capacitor, the switch circuit, the second capacitor, and the third resistor circuit, the voltage across the capacitor rises to a voltage related to the power source voltage even though the rate of rise in voltage across the capacitor decreases due to connection of the third resistor circuit.

In the present invention, even after the switch circuit turns OFF, display of the power source voltage continues during the period that the voltage across the capacitor is greater than a prescribed voltage. As a result, after operator action causes the switch circuit to turn OFF, power source voltage display continues until the voltage across the capacitor decays to the prescribed voltage, and that capacitor voltage decay is a function of the power source voltage and the time constant of the parallel-connection of the capacitor and second resistor circuit.

In the present invention, voltage divided from the power source voltage when the voltage across the capacitor is greater than a prescribed voltage is compared in comparator circuits with voltages divided from a reference voltage generated from the external power source when the voltage across the capacitor is greater than a second voltage that is different from the prescribed voltage. Display devices are illuminated according to the comparator circuit results. Consequently, the results of comparison of the voltage divided power source voltage with voltages divided from the reference voltage are indicated by illumination or non-illumination of the display devices.

In the present invention, since the second voltage is lower than the prescribed voltage, the reference voltages for comparison are applied to the comparator circuits prior to application of the voltage (voltage divided power source voltage) for comparison. Consequently, when the voltage across the capacitor is lower than the prescribed voltage but higher than the second voltage, display device illumination is reliably prevented. Further, when the voltage across the capacitor is higher than the prescribed voltage, the display devices are illuminated or not illuminated in accordance with the value of the power source voltage.

In the present invention, depending on the voltage rise across the capacitor, voltage divided from the external power source, and depending on the voltage rise across the capacitor, voltages divided from a reference voltage generated from the external power source are compared in comparator circuits and display devices are illuminated according to the comparison results. Consequently, the display devices are illuminated or not illuminated according to the results of comparing the voltage divided power source voltage with the voltages divided from reference voltage.

In the present invention, rechargeable battery voltage is displayed by the voltage indicating apparatus described above. Accordingly, a voltage indicating apparatus, which allows continued power source voltage display after an operator action to display voltage where the continued voltage display has no dependence on the length of time of the operator action, is applied in a battery pack.

According to the present invention, a second capacitor is connected to the node between one end of a resistor circuit that is connected to a power source terminal at the other end, and one end of a switch circuit that is connected to the capacitor at the other end. During the initial OFF period of the switch circuit, the power source charges the second capacitor towards the power source voltage through the resistor circuit. When the switch circuit is turned ON, the capacitor becomes connected in parallel with the second capacitor through the switch circuit and the voltage across the capacitor rapidly increases to a voltage related to the power source voltage. Further, when the switch circuit turns OFF, display based on the power source voltage continues even as the voltage across the capacitor decays according to the time constant of the parallel-connection of the capacitor and second resistor circuit. Accordingly, the continued display time does not depend on the time that the switch circuit was in the ON state. Therefore, continued power source indication after an operator action to display voltage is possible independent of the length of time of the operator action. The above and further objects of the present invention as well as the features thereof will become more apparent from the following detailed description to be made in conjunction with the accompanying drawings.

### BRIEF DESCRIPTION OF THE DRAWINGS

FIG. 1 is an abbreviated circuit diagram showing an example of the circuit structure for a battery pack of the present invention;

FIG. 2 is an abbreviated circuit diagram showing an example of the circuit structure of a voltage indicating apparatus; and

FIG. 3 is a timing diagram illustrating operation of the voltage indicating apparatus when the switch circuit is switched ON and OFF.

### DETAILED DESCRIPTION OF THE EMBODIMENT

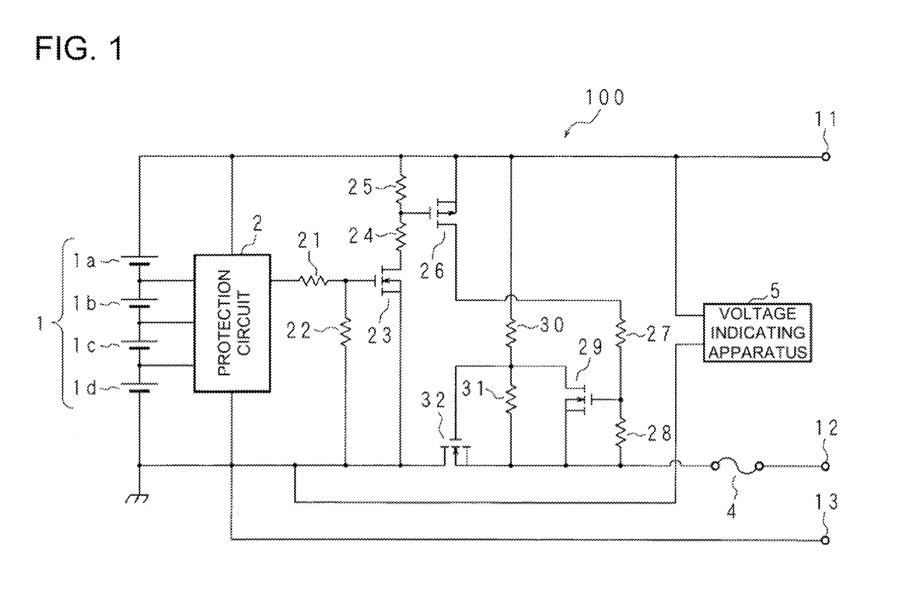

The following describes in detail an embodiment of the present invention based on the figures. FIG. 1 is an abbreviated circuit diagram showing an example of the circuit structure for a battery pack of the present invention. The battery pack 100 in this figure is provided with a rechargeable battery 1 that is a lithium ion battery (for example), and a voltage indicating apparatus 5 connected across the rechargeable battery 1 terminals to display battery voltage. The rechargeable battery 1 has battery cells 1a, 1b, 1c, 1d connected in series in that order. The rechargeable battery 1 can also be a different type of battery such as a nickel hydride battery or nickel cadmium battery. The positive electrode of the battery cell 1a is connected to a positive electrode terminal 11 for the purpose of drawing current to the outside, and the negative electrode of the battery cell 1d establishes ground potential. One side of a thermal fuse 4 in the rechargeable battery 1 negative-side charging and discharging circuitry is connected to a negative electrode terminal 12 that forms a pair with the positive electrode terminal 11 for charging. The negative electrode terminal 13 for discharging is connected to ground.

The voltage of each battery cell 1a, 1b, 1c, 1d is applied to respective input terminals of a protection circuit 2 that detects over-voltage for a plurality of battery cells. A series-connection of resistors 21, 22 (i.e. a voltage divider) is connected between the protection circuit 2 output terminal and ground. Note the number of battery cells is not limited to four, and for example, a rechargeable battery with ten battery cells connected in series is also possible. In that case, the voltages of four battery cells, three battery cells, and three battery cells are applied respectively to the input terminals of three protection circuits. Voltages output from each of the three protection circuits are then converted to current values, the currents are added, the result is converted back to a voltage, and that voltage is applied to the series-connected resistors.

The node between resistors 21, 22 is connected to the gate of an N-channel metal-oxide-semiconductor field-effect transistor (MOSFET) 23 with a grounded-source, and a series-connection of resistors 24, 25 is connected between the MOSFET 23 drain and the positive electrode terminal 11. The node between resistors 24, 25 is connected to the gate of a P-channel MOSFET 26 with its source connected to the positive electrode terminal 11, and a series-connection of resistors 27, 28 is connected between the MOSFET 26 drain and the battery-side of the thermal fuse 4.

The node between resistors 27, 28 is connected to the gate of an N-channel MOSFET 29 with its source connected to the battery-side of the thermal fuse 4. The drain of MOSFET 29 is connected to the node between series-connected resistors 30, 31, and that node is also connected to the gate of an N-channel MOSFET with its drain connected to the ground line. One end of the series-connected resistors 30, 31 is connected to the positive electrode terminal 11, and the other end is connected to the battery-side of the thermal fuse 4 and the source of MOSFET 32.

In this circuit structure, when an over-voltage is detected in any one of the battery cells 1a, 1b, 1c, 1d, voltage output from the protection circuit 2 output terminal is voltage divided by resistors 21, 22 to turn ON the MOSFET 23 and pull its drain voltage down to (approximately) ground level. Accordingly, a negative gate-to-source voltage applied to (P-channel) MOSFET 26 turns that device ON, a positive gate-to-source voltage turns MOSFET 29 ON, and as a result, the gate-to-source voltage applied to MOSFET 32 (initially biased ON by resistors 30, 31) drops to (approximately) zero. Therefore, MOSFET 32 has no gate-to-source voltage and is turned OFF cutting-off electrical connection between the negative electrode terminal 12 for charging and ground potential. As a result, no rechargeable battery 1 voltage is applied between the positive electrode terminal 11 and the negative electrode terminal 12 for charging. By turning OFF the MOSFET 32, the flow of charging current can be interrupted and over-charging can be prevented. Note that during rechargeable battery 1 discharging, the negative electrode terminal 13 for discharging is used.

Here, an example of rechargeable battery 1 protection from over-voltage by the protection circuit 2 was shown in FIG. 1. However, circuitry to detect an over-voltage that is on the order of 0.1V higher than the over-voltage detected by the protection circuit 2 can be added to the circuit of FIG. 1 for more reliable rechargeable battery 1 over-voltage protection. Further, to reduce local signal noise in various parts of the circuit (and circuits described below), capacitors and/or resistors can be appropriately added as necessary.

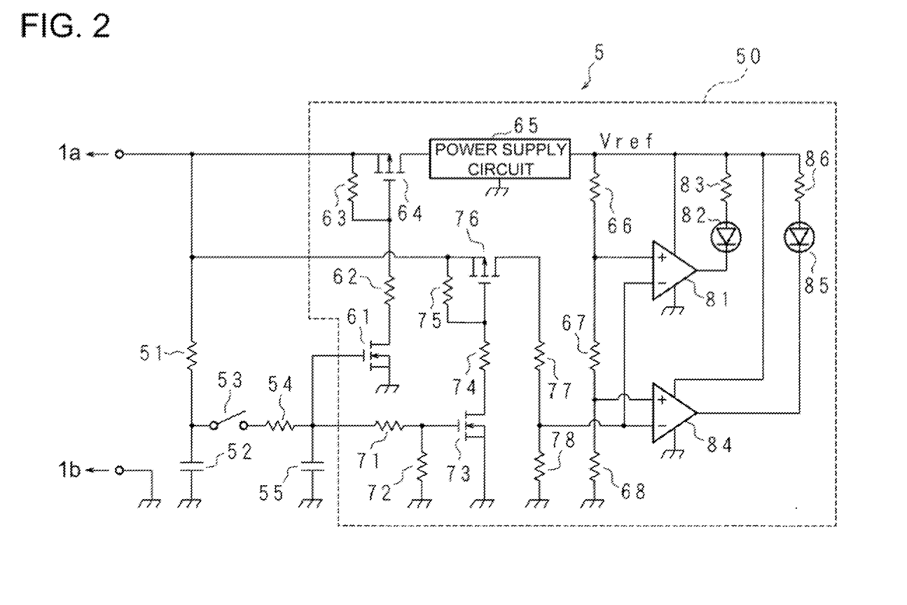

The following describes a voltage indicating apparatus 5. FIG. 2 is an abbreviated circuit diagram showing an example of the circuit structure of a voltage indicating apparatus 5. The voltage indicating apparatus 5 is provided with a resistor (resistor circuit) 51 with one end connected to the rechargeable battery (positive electrode of battery cell 1a), and a capacitor (second capacitor) 52 with one end connected to ground (negative electrode of battery cell 1d). The other (common) terminals of the resistor 51 and capacitor 52 are connected through a switch 53 and resistor 54 to a node that is connected to a capacitor 55 grounded at the opposite end, to the gate of a grounded-source N-channel MOSFET 61, and to a series-connection of resistors 71, 72 (i.e. a voltage divider) grounded at the opposite end. The switch 53 is a push-button-switch of the type referred to as “normally open.”

Series-connected resistors 62, 63 are connected between the drain of MOSFET 61 and the (battery cell 1a) positive-battery-electrode-side of resistor 51, and the node between resistors 62, 63 is connected to the gate of a P-channel MOSFET 64 that has its source connected to the positive-battery-electrode-side of resistor 51. The drain of MOSFET 64 is connected to the input terminal of a power supply circuit 65, and a series-connection of resistors 66, 67, 68 (i.e. a voltage divider) is connected between the power supply circuit 65 output terminal and ground. The power supply circuit 65 stabilizes voltage applied via the source and drain of MOSFET 64 and generates a reference voltage Vref (5V DC in the present embodiment).

The node between resistors 71, 72 is connected to the gate of a grounded source N-channel MOSFET 73, and a series-connection of resistors 74, 75 is connected between the drain of MOSFET 73 and the positive-battery-electrode-side of resistor 51. The node between resistors 74, 75 is connected to the gate of a P-channel MOSFET 76 that has its source connected to the positive-battery-electrode-side of resistor 51, and a series-connection of resistors 77, 78 (i.e. a voltage divider) is connected between the drain of MOSFET 76 and ground.

The voltage indicating apparatus 5 is also provided with comparators 81, 84 powered by the reference voltage Vref. Voltage at the node between resistors 66, 67 and voltage at the node between resistors 67, 68 are applied respectively to the non-inverting inputs of the comparators 81, 84, and the voltage at the node between resistors 77, 78 is applied to the inverting input of both comparators 81, 84. The output terminals of the comparators 81, 84 are connected to the cathodes of LEDs 82, 85, and the anodes of the LEDs 82, 85 are connected through resistors 83, 86 to the output terminal of the power supply circuit 65.

In the circuit structure of the voltage indicating apparatus 5 shown in FIG. 2, circuitry other than the resistors 51, 54, capacitors 52, 55, and switch 53 makes up a display section 50. Further, the display section 50 is not limited to two comparators. The display section 50 can also be provided with three or more comparators each having a different voltage divided from the reference voltage Vref applied to the non-inverting input, and having the output terminal connected to an LED and resistor in series. In this case, the voltage at the node between resistors 77, 78 is applied to the inverting input of each comparator.

In the display section 50, while the device characteristics of MOSFETs 61, 73 are selected to turn ON at approximately the same gate voltage, the voltage applied to the gate of MOSFET 61 is applied to the gate of MOSFET 73 after being voltage divided by the voltage divider resistors 71, 72. Therefore, when the voltage across capacitor 55 rises (or decays), MOSFET 61 will turn ON first (or MOSFET 73 will turn OFF first). This is described in greater detail later.

When MOSFET 61 is turned ON, a negative gate-to-source voltage is applied to P-channel MOSFET 64 to turn that device ON and apply the rechargeable battery 1 voltage (subsequently referred to as the battery voltage) to the power supply circuit 65. The reference voltage Vref generated by the power supply circuit 65 is applied to the series-connected resistors 66, 67, 68. As a result, two voltages divided from the reference voltage Vref, which are a first comparison voltage and a second comparison voltage that is lower than the first comparison voltage, are applied respectively to the non-inverting inputs of the comparators 81, 84.

When MOSFET 73 turns ON, a negative gate-to-source voltage is applied to P-channel MOSFET 76 to turn that device ON and apply the battery voltage from the drain of MOSFET 76 to the series-connected resistors 77, 78. This applies the battery voltage divided by the voltage divider resistors 77, 78 to the inverting inputs of both comparators 81, 84. When the voltage applied to the inverting input of each comparator 81, 84 is greater than the voltage applied to the non-inverting input, the LEDs 82, 85 are illuminated. Accordingly, if the battery voltage is considered to reflect the remaining capacity of the rechargeable battery 1, rechargeable battery 1 remaining capacity can be ascertained from the illuminated LEDs 82, 85.

Based on the description above, if the battery voltage divided by resistors 77, 78 is greater than the first comparison voltage, both LEDs 82, 85 are illuminated, if the voltage divided battery voltage is less than the first comparison voltage but greater than the second comparison voltage, LED 85 is illuminated, and if the voltage divided battery voltage is less than the second comparison voltage, both LEDs 82, 85 are OFF. Specifically, if the threshold battery voltages that should illuminate the LEDs 82, 85 are Va and Vb respectively, then the ratio of the second comparison voltage to the first comparison voltage is made equal to the ratio of Vb to Va. Further, the first comparison voltage (or the second comparison voltage) can simply be made equal to Va (or Vb) times the voltage divider ratio of resistors 77, 78.

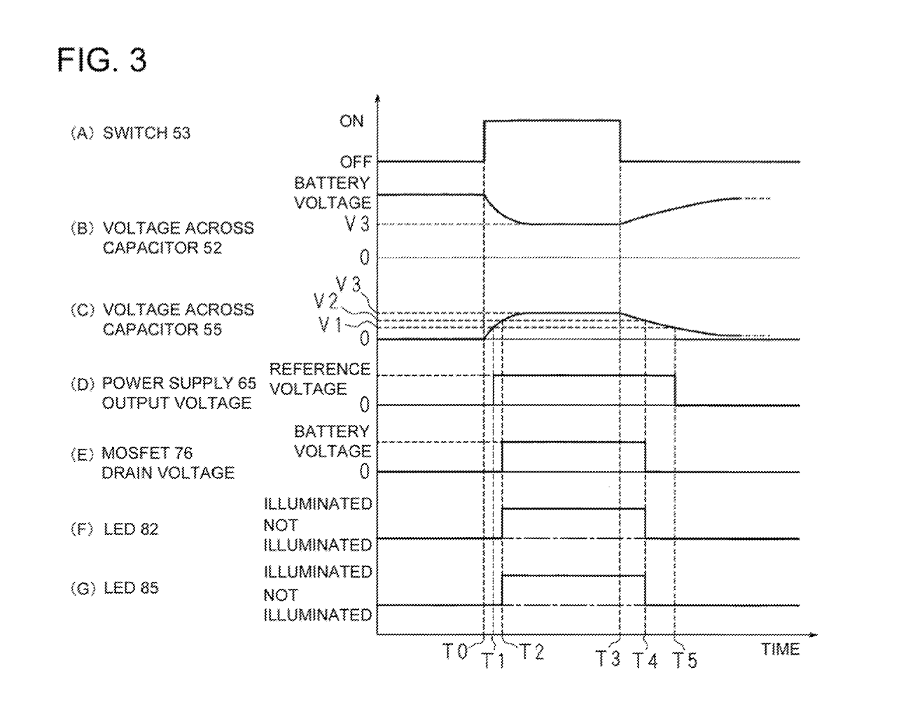

The following describes operation of the circuit in FIG. 2 using a timing diagram. FIG. 3 is a timing diagram illustrating operation of the voltage indicating apparatus 5 when the switch 53 is switched ON and OFF. In FIG. 3 (A)-(G), the horizontal axis represents time, and the vertical axes show the state or voltage of each signal. However, voltages indicated by the vertical axes of FIG. 3 (B)-(E) are not necessarily the same scale.

FIG. 3 (A) shows the ON-OFF state of the operator activated switch 53.

FIG. 3 (B) shows the voltage across the capacitor 52 with discharging and charging due to switch 530N-OFF switching.

FIG. 3 (C) shows the voltage across the capacitor 55 with charging and discharging due to switch 530N-OFF switching.

FIG. 3 (D) shows the output voltage of the power supply circuit 65 that generates a reference voltage based on the battery voltage.

FIG. 3 (E) shows the battery voltage at the drain of MOSFET 76 that is applied to the series-connected resistors 77, 78.

FIG. 3 (F), (G) shows the state of each LED 82, 85 illuminated by the respective comparator 81, 84.

Prior to time T0, capacitor 52 is charged to the battery voltage through resistor 51. In the present embodiment, the time constant of resistor 51 and capacitor 52 is approximately 10 sec, but is not limited to that value. Meanwhile, capacitor 55 is connected across the series-connection of resistors 71, 72, and its voltage is 0V.

When the operator presses the push-button-switch 53 to turn it ON at time T0, charge accumulated in capacitor 52 transfers to capacitor 55 through the switch 53 and resistor 54. In the present embodiment, the capacitance of the two capacitors 52, 55 are equal, and since capacitor charge is proportional to the product of the voltage and capacitance (Q=CV), the rise in voltage across capacitor 55 is just equal to the drop in voltage across capacitor 52. The rise or drop in voltages across the capacitors 55, 52 continues until the voltage across both capacitors 52, 55 is equal. However, the capacitance of capacitors 55, 52 does not necessarily have to be equal, and the capacitance ratio can be set as convenient.

When the switch 53 is ON, capacitor 52, resistor 54, and capacitor 55 are connected in series through ground, and the time constant of that series circuit is the product of the total combined series capacitance of the two capacitors 52, 55 and the resistance of resistor 54. In the present embodiment, that time constant is 1 msec, which is sufficiently shorter than the time that an operator is likely to press the push-button-switch. Therefore, it can be assumed that charge transfer from capacitor 52 to capacitor 55 is completed prior to the time that the switch 53 turns OFF (T3).

At time T1, when the voltage across capacitor 55 rises to V1 and MOSFET 61 turns ON before MOSFET 73, the output voltage of the power supply circuit 65 supplied with battery voltage becomes the reference voltage Vref. At this time, since the MOSFETs 73, 76 are not ON, voltage applied to the inverting inputs of comparators 81, 84 is 0V, and the LEDs are not illuminated.

Next, at time T2 when the voltage across capacitor 55 rises to V2 and the MOSFET 73 turns ON, MOSFET 76 also turns ON and voltage at the drain of MOSFET 76 becomes the battery voltage. From that time point, the battery voltage divided by the voltage divider resistors 77, 78 is applied to the inverting inputs of the comparators 81, 84, which perform comparison of the voltages applied to the inverting and non-inverting inputs of each comparator 81, 84. The LEDs 82, 85 are illuminated (solid lines in FIG. 3 (F), (G)) or not illuminated (broken lines in FIG. 3 (F), (G)) in accordance with the comparison results.

Subsequently, the voltage across capacitor 55 rises towards V3, and the voltage across capacitor 52 decays towards V3. As described previously, in the present embodiment, since the rise in voltage across capacitor 55 is equal to the drop in voltage across capacitor 52, the battery voltage minus V3 is equal to V3, and V3 is equal to half the battery voltage. In general however, the drop in capacitor 52 voltage from the battery voltage is equal to the ratio of the capacitance of capacitor 55 to the capacitance of capacitor 52 times V3.

Next, when the operator releases the push-button-switch to turn it OFF at time T3, capacitor 52 again begins charging in accordance with the 10 sec time constant mentioned previously. Meanwhile, since the series-connected resistors 71, 72 are connected in parallel with capacitor 55; it begins discharging according to the time constant of that parallel circuit. In the present embodiment, that parallel circuit time constant is approximately 4.4 sec, and accordingly, the capacitor 55 gradually discharges over a period on the order of seconds.

Next, when the voltage across capacitor 55 drops to V2 at time T4, MOSFET 73 turns OFF turning OFF MOSFET 76, and the voltage at the drain of MOSFET 76 becomes 0V. Accordingly, the voltage applied to the inverting inputs of the comparators 81, 84 again becomes zero. As a result, illumination or non-illumination of the LEDs 82, 85 continues to this time point.

At time T5, when the voltage across capacitor 55 drops to V1, MOSFET 61 turns OFF, and as a result, MOSFET 64 also turns OFF. With MOSFET 64 OFF, the voltage supplied to the power supply circuit 65 as well as its output voltage become 0V. During the period from T4 to T5, non-illumination of the LEDs 82, 85 is assured because no voltage is applied to the inverting inputs of the comparators 81, 84.

In the present embodiment as described above, the series-connection of resistor 51 and switch 53 is connected between the rechargeable battery 1 and capacitor 55, the resistor 51 is connected to the rechargeable battery 1, and capacitor 52 is connected to the node between the resistor 51 and the switch 53. Initially when the switch 53 is OFF, the capacitor 52 is charged from the rechargeable battery 1 through the resistor 51 towards the battery voltage. When the switch 53 is turned ON, capacitor 55 becomes connected in parallel with capacitor 52 through the switch 53, and the voltage across capacitor 55 rapidly increases to a voltage (V3) related to the battery voltage. When the switch 53 is turned OFF, the voltage across capacitor 55 decays continuously according to the time constant of the parallel circuit formed by capacitor 55 and the series-connected resistors 71, 72. Since voltage display continues even as capacitor 55 voltage continues to decay, the extended display time does not depend on the time that the switch 53 was in the ON state. As a result, continued power source voltage indication after operator, action to display that voltage does not depend on the length of time of the operator action.

Further, since rechargeable battery 1 voltage is displayed, it is possible to accurately ascertain the remaining battery capacity.

Further, since resistor 54 is added in series with the series-connection that includes capacitor 55, switch 53, and capacitor 52, current that flows from capacitor 52 through switch 53 to capacitor 55 when the switch 53 is turned ON can be prevented from exceeding the rated current of the switch 53. Since the time that the operator presses the switch 53 ON can be assumed sufficiently longer than the time based on the time constant of the capacitor 52, switch 53, resistor 54, and capacitor 55 series circuit, the voltage across capacitor 55 can rise to voltage (V3) even though that voltage rise is slowed by connection of resistor 54.

Further, even when the switch 53 turns OFF, display corresponding to the battery voltage continues during the period that voltage across capacitor 55 is greater than a prescribed voltage (V2). Specifically, after the switch 53 turns OFF due to operator action, continued voltage display is possible until the voltage across capacitor 55 drops to the prescribed voltage (V2) in accordance with the battery voltage and the time constant of the parallel circuit formed by capacitor 55 and the series-connection of resistors 71, 72.

Still further, battery voltage divided by voltage divider resistors 77, 78 when capacitor 55 voltage is greater than a prescribed voltage (V2), and voltages divided from a reference voltage Vref generated from the battery voltage when capacitor 55 voltage is greater than a second voltage (V1) are compared by comparators 81, 84, and display devices 82, 85 are illuminated according to the comparison results. Accordingly, display devices 82, 85 can be illuminated or not illuminated according to the results of comparing the voltage divided battery voltage with voltages divided from the reference voltage Vref.

Still further, since the second voltage (V1) is lower than the prescribed voltage (V2), the comparison reference voltages are applied to the comparators 81, 84 prior to application of the voltage (divided battery voltage) to be compared. Accordingly, when the voltage across the capacitor 55 is lower than the prescribed voltage but greater than the second voltage, display device 82, 85 illumination is reliably prevented, and when the voltage across the capacitor 55 is greater than the prescribed voltage, the display devices 82, 85 can be illuminated or not illuminated corresponding to value of the battery voltage.

Still further, depending on the voltage rise across the capacitor 55, battery voltage divided by the voltage divider resistors 77, 78, and depending on the voltage rise across the capacitor 55, voltages divided from the reference voltage Vref generated from the battery voltage are compared in comparators 81, 84 and the display devices 82, 85 are illuminated according to the comparison results. Accordingly, display devices 82, 85 can be illuminated or not illuminated according to the results of comparing the voltage divided battery voltage with voltages divided from the reference voltage Vref.

Still further, rechargeable battery 1 voltage is displayed by the voltage indicating apparatus 5. Accordingly, a voltage indicating apparatus 5 that makes it possible to continue voltage display after operator action to display that voltage, where the continued display time does not depend on the length of time for the operator action, can be applied in a battery pack 100.

Note in the present embodiment, a resistor 54 was connected in series with the switch 53. However, depending on the switch 53 contact capacitance and the capacitance of capacitors 52, 55, parasitic resistance in the circuit can substitute for resistor 54, which can be reduced without limit towards a 0Ω value.

It should be apparent to those with an ordinary skill in the art that while various preferred embodiments of the invention have been shown and described, it is contemplated that the invention is not limited to the particular embodiments disclosed, which are deemed to be merely illustrative of the inventive concepts and should not be interpreted as limiting the scope of the invention, and which are suitable for all modifications and changes falling within the spirit and scope of the invention as defined in the appended claims. The present application is based on Application No. 2011-007,942 filed in Japan on Jan. 18, 2011, the content of which is incorporated herein by reference.

What is claimed is:

1. A method of indicating voltage that displays power source voltage with a voltage indicating apparatus comprising: a capacitor connected to the external power source through series-connection of a resistor circuit and a switch circuit; a second resistor circuit connected in parallel with the capacitor; and a display section that makes indications based on the voltage across the capacitor, the method comprising:
establishing the resistor circuit closer to the power source than the switch circuit;
providing a second capacitor that is connected to the node between the resistor circuit and the switch circuit; and
turning OFF the switch circuit after the switch circuit is switched ON.

2. The method of indicating voltage as cited in claim 1 wherein the power source is a battery.

3. The method of indicating voltage as cited in claim 1 further comprising:
providing a third resistor circuit that is connected in series with the series circuit that includes the capacitor, the switch circuit, and the second capacitor,
wherein the length of time that the switch circuit is in the ON state is longer than a time corresponding to the time constant of the series circuit that includes the third resistor circuit.

4. A voltage indicating apparatus comprising:
a capacitor connected to an external power source through series-connection of a resistor circuit and a switch circuit;
a second resistor circuit connected in parallel with the capacitor; and
a display section that makes indications based on the voltage across the capacitor,
wherein the resistor circuit is connected closer to the power source than the switch circuit, and
a second capacitor is provided that is connected to the node between the resistor circuit and the switch circuit.

5. The voltage indicating apparatus as cited in claim 4 wherein the power source is a battery.

6. The voltage indicating apparatus as cited in claim 4 wherein a third resistor circuit is connected in series with the series circuit that includes the capacitor, the switch circuit, and the second capacitor

7. The voltage indicating apparatus as cited in claim 4 wherein the display section makes prescribed indications when the voltage across the capacitor is greater than a prescribed voltage.

8. The voltage indicating apparatus as cited in claim 7 wherein the display section comprises:
a voltage divider circuit that divides the power source voltage when the voltage across the capacitor is greater than the prescribed voltage;
a power supply circuit that generates a reference voltage from the power source voltage when the voltage across the capacitor is greater than a second voltage that is different from the prescribed voltage;
comparator circuits that compare the voltage divider circuit voltage with voltages divided from the reference voltage; and
display devices that illuminate according to the comparator circuit results.

9. The voltage indicating apparatus as cited in claim 8 wherein the second voltage is lower than the prescribed voltage.

10. The voltage indicating apparatus as cited in claim 4 wherein the display section comprises:
a voltage divider circuit that divides the power source voltage in compliance with voltage rise across the capacitor;
a power supply circuit that generates a reference voltage from the power source voltage in compliance with voltage rise across the capacitor;
comparator circuits that compare the voltage divider circuit voltage with voltages divided from the reference voltage; and
display devices that illuminate according to the comparator circuit results.

11. A battery pack provided with the voltage indicating apparatus as cited in claim 4 and a rechargeable battery that has its (have their) voltage indicated by the voltage indicating apparatus.
